(19) United States
(12) Patent Application Publication
(10) Pub. No.: US 2004/0032919 A1
(43) Pub. Date: Feb. 19, 2004

(54) Enhanced DC offset mitigation

(76) Inventors: Asim Loan, Los Angeles, CA (US); Dennis Lai, Cerritos, CA (US); Meng-Chang Doong, Alhambra, CA (US)

Correspondence Address: Jonathan W. Hallman, MacPHERSON KWOK CHEN & HEID LLP, Suite 210, 2402 Michelson Drive, Irvine, CA, 92612, US

(21) Appl. No.: 10/222,312

(22) Filed: Aug. 16, 2002

(51) Int. Cl. H04L 1/00; H03D 1/04

(52) U.S. Cl. 375/346

(57) ABSTRACT

A technique is disclosed to estimate the frequency offset in received direct downconverted predetermined signal despite the presence of a DC offset component. After compensation of the received predetermined signal according to the frequency offset estimation, the DC offset component is estimated. DC offset in data signals subsequent to the predetermined signal may then be mitigated based upon the estimated DC offset component.

### FIELD OF INVENTION

This invention relates to direct down conversion and more specifically to mitigating the DC offset component in a direct-down-converted signal.

### BACKGROUND

Radio receivers typically employ a superheterodyne architecture. In this architecture, the receiver uses two stages to translate an RF signal from a carrier frequency to an intermediate frequency (IF) and then to baseband. In contrast, a direct downconversion receiver uses just one stage to translate an RF signal directly from the carrier frequency to baseband. Because the extra stage in a superheterodyne receiver inevitably introduces additional noise (thereby degrading the signal-to-noise ratio) and requires more components (making production more costly), direct downconversion receivers pose an attractive alternative to the prevalent superheterodyne architecture.

In a direct downconversion receiver, the RF signal is mixed with a local oscillator (LO) signal. Inevitably, this process produces an undesired self mixing of the LO signal, thereby producing both a DC offset component and a high frequency component. For example, if the LO signal is represented by the sinusoid cos(ωt), the self mixing produces the product:

cos(ωt)*cos(ωt)=½(the DC offset component)+cos(2ωt)/2 (the high frequency component).

The high frequency component may be filtered off. However, the DC offset component can wreak havoc in subsequent baseband processing, particularly for higher throughput modulations. For example, FIG. 1 shows the potential locations 10 in signal space for a QPSK-modulated signal. Signals 12 show the subsequent location in signal space should an arbitrary DC offset component be present. Although distorted, signals 12 may still be correctly demodulated. But should the same DC offset component be present for signals 14 in a 16-QAM modulation scheme as shown by resulting signals 16 in FIG. 2, errors may result as indicated by locations 16a. Accordingly, the presence of a DC offset poses a serious problem for any direct-downconverted receiver architecture. A superheterodyne receiver, however, may filter off the DC offset components because of the extra stage of processing. Thus, despite their inferior noise properties and higher manufacturing costs, superheterodyne receivers are more popular than direct downconversion receivers.

To realize the benefits of a direct downconversion receiver, something must be done to mitigate the DC offset component. For example, the DC offset component may be estimated so that it may be subsequently compensated for at baseband. But the measurement of the DC offset component becomes problematic should a frequency offset be present between the receiver and the transmitter. Such a frequency offset is inherent in any communication system, particularly in mobile applications subject to Doppler effects.

Accordingly, there is a need in the art for improved techniques to estimate the DC offset component despite the presence of a frequency offset between the receiver and transmitter.

### SUMMARY

In accordance with one aspect of the invention, a method of mitigating a DC offset component in a received data sample subject to a frequency offset includes an act of receiving a sequence of samples of a predetermined signal, wherein the predetermined signal is periodic over n samples. Because the predetermined signal is periodic with respect to n samples, the frequency-offset-induced phase shift between successive received samples of the predetermined signal may be estimated by comparing received samples in a first period of the predetermined signal to the corresponding received samples in a second period of the predetermined signal. The DC offset component in the received samples of the predetermined signal may then be estimated after compensating the received samples based upon the estimated frequency-offset-induced phase shift. This estimated DC offset component may then be cancelled for in the received data sample.

In accordance with another aspect of the invention, a baseband processor includes a state machine for estimating a frequency-offset-induced phase shift between successive received samples of a predetermined signal, wherein the transmitted samples of the predetermined signal are periodic. The state machine estimates this phase shift by comparing received samples in a first period of the predetermined signal to the corresponding received samples in a second period of the predetermined signal. The state machine is further configured to estimate a DC offset component in the received samples of the predetermined signal after compensating the received samples according to the estimated phase shift.

The invention will be more fully understood upon consideration of the following detailed description, taken together with the accompanying drawings.

### BRIEF DESCRIPTION OF THE DRAWINGS

FIG. 1 illustrates the effect of a DC offset component on the potential locations in signal space for a QPSK-modulated signal.

FIG. 2 illustrates the effect of a DC offset component on the potential locations in signal space for a 16-QAM-modulated signal.

FIG. 3 is a z-transform representation of a prior art averaging technique that estimates the DC component without accounting for frequency offsets.

FIG. 4 is a shift register implementation for the technique illustrated in FIG. 3.

FIG. 5 is a z-transform representation of a circuit to estimate the DC offset component in the presence of a frequency offset according to one embodiment of the invention.

FIG. 6 is a partial block diagram for a DC offset cancellation processor according to one embodiment of the invention.

FIG. 7 is a z-transform implementation of a frequency offset estimation technique that does not compensate for the presence of a DC offset component according to one embodiment of the invention.

FIG. 8 is a z-transform implementation of a frequency offset estimation technique independent of the presence of a DC offset component according to one embodiment of the invention.

FIG. 9 is a block diagram for a DC offset cancellation processor according to one embodiment of the invention.

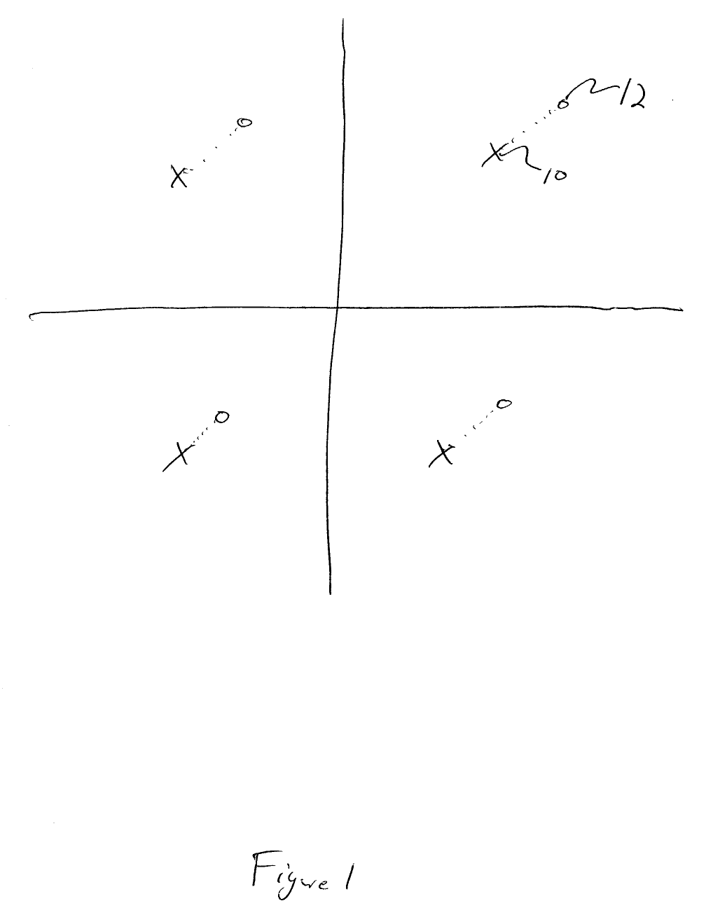

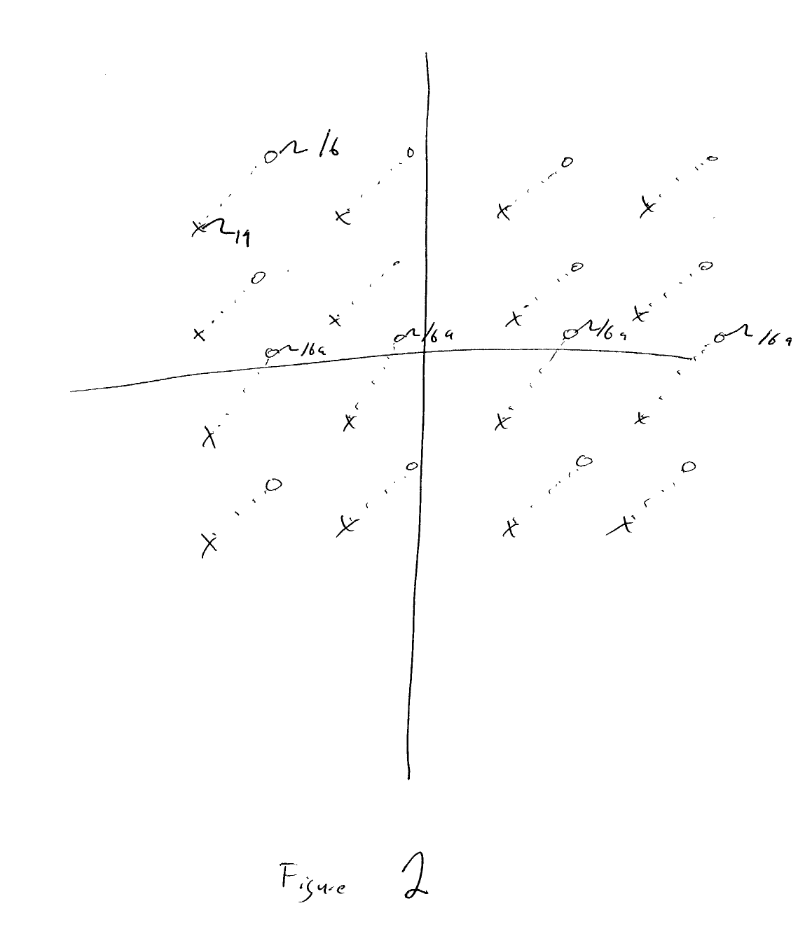

### DETAILED DESCRIPTION

In networks such as a wireless LAN, data transmission occurs in bursts or packets of data. Each burst of data may be pre-pended with a preamble that is known to the receiver. Because the characteristics of this preamble are known apriori to the receiver, it may be used for signal up detection, automatic gain control (AGC), antenna diversity implementation, and receiver synchronization. As will be explained further herein, the known characteristics of the preamble may also be exploited by the receiver to aid in DC offset component estimation.

For example, in an IEEE 802.11a waveform, the preamble consists of ten identical sequences each of length sixteen. Each sequence has an average value of zero. Thus, by summing over all sixteen samples in each sequence, a DC offset component may be estimated. Mathematically, the kth received sample \tilde{r}ₖ may be given by:

\tilde{r}ₖ=\tilde{p}ₖ+\tilde{V}_{DC}

where \tilde{V}_{DC} is the DC offset component for each received sample and \tilde{p}ₖ is the transmitted kth sample of the preamble. Those of ordinary skill will appreciate that these signals may be complex or real depending upon the signal representation. It follows that:

$${\sum }_{k = 0}^{n - 1} {\tilde{r}}_{k} = {\sum }_{k = 0}^{n - 1} {\tilde{p}}_{k} + n {\tilde{V}}_{D C}$$

where n is the number of samples for summation. A typical value of n for an IEEE 802.11a application would be 16 or 32. After rearrangement, the previous equation becomes:

$${\tilde{V}}_{D C} = \frac{{\sum }_{k = 0}^{n - 1} {\tilde{r}}_{k} - {\sum }_{k = 0}^{n - 1} {\tilde{p}}_{k}}{n}$$

The known periodic characteristics of the preamble may be used to solve for the DC component. Assuming an IEEE 802.11a application, the average value of the n samples in a complete sequence from a preamble is zero such that:

$${\sum }_{k = 0}^{n - 1} {\tilde{p}}_{k} = 0$$

resulting in the following expression for \tilde{V}_{DC}:

$${\tilde{V}}_{D C} = \frac{1}{n} {\sum }_{k = 0}^{n - 1} {\tilde{r}}_{k}$$

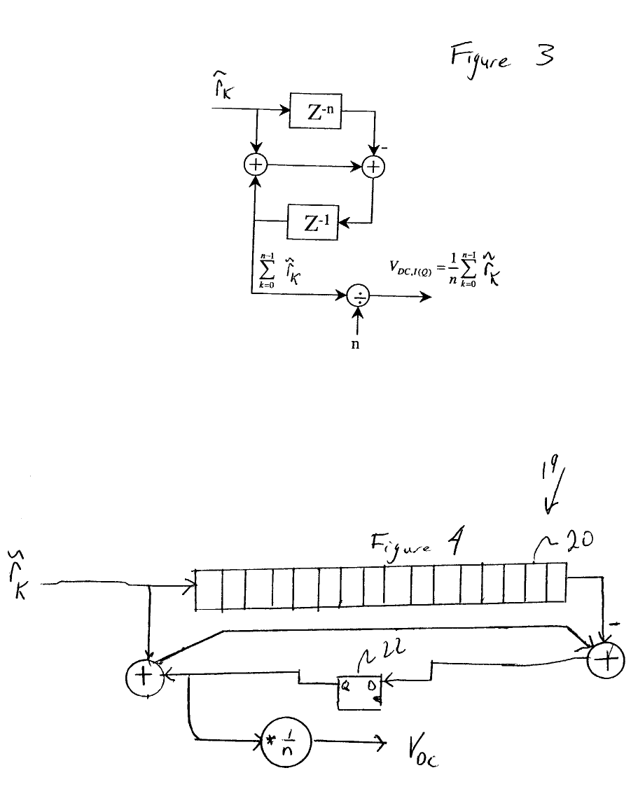

FIG. 3 illustrates a z-transform implementation of the previous derivation for the DC offset component. It will be appreciated that a variety of circuits may be used to implement the z-transform representation of FIG. 3. For example, FIG. 4 shows an averaging circuit 14 that estimates \tilde{V}_{DC} using a 16-bit shift register 20 and a D-type flip-flop 22. Averaging circuit 14 may be implemented for both the in-phase (I) and the quadrature-phase (Q) signal components.

The averaging approach discussed with respect to FIGS. 3 and 4 becomes problematic, however, should a frequency offset be present in the received signal from a Doppler shift or other effects. Because the frequency offset is not known, the characteristics of the received signal cannot be predicted apriori despite the known characteristics of the preamble. For example, let ωₒ be the frequency offset and ωₛ be the sampling frequency. The received signal then becomes:

\tilde{r}ₖ=\tilde{p}ₖe^{jφ}^{ₖ}+\tilde{V}_{DC} Equation (1)

where φₖ=k−φₒ and φₒ=. Summing all received signal samples over n gives:

$${\sum }_{k = 0}^{n - 1} {\tilde{r}}_{k} = {\sum }_{k = 0}^{n - 1} {\tilde{p}}_{k} {ⅇ}^{j {φ}_{k}} + n {\tilde{V}}_{D C}$$

Solving for \tilde{V}_{DC} in the previous equation gives:

$${\tilde{V}}_{D C} = \frac{1}{n} ( {\sum }_{k = 0}^{n - 1} {\tilde{r}}_{k} - {\sum }_{k = 0}^{n - 1} {\tilde{p}}_{k} {ⅇ}^{j {φ}_{k}} )$$

where the second term in the parenthesis is not zero if a frequency offset exists.

Accordingly, the performance of communication systems that estimate the DC offset component using the averaging approach of FIG. 3 is not very encouraging should even a small frequency offset be present. The frequency offset should be removed before a reliable DC offset estimation can be performed. The present invention provides two techniques to estimate and remove the frequency offset. In a first technique, the frequency offset is estimated in the presence of the DC offset component. In a second technique, the estimate from the first technique is refined by removing the influence of the DC offset component. Regardless of the estimation technique implemented, the following approach may be used to mitigate the DC offset component in the presence of a frequency offset in a direct-down converted signal such as that produced by the receiver architecture disclosed in the co-pending U.S. pat. application Ser. No. ______, entitled “Zero Intermediate Frequency to Low Intermediate Frequency Receiver Architecture,” Attorney docket no. M-15027, filed ______, 2002, the contents of which are hereby incorporated by reference.

If the estimated frequency offset is represented by \hat{ω}ₒ, the estimated amount of frequency-offset-induced phase shift between each received sample of the preamble would be

$${\hat{φ}}_{o} = 2 π \frac{{\hat{ω}}_{o}}{{ω}_{s}} .$$

From equation (1) and the estimated amount of phase shift \hat{φ}ₒ in each received sample, the following estimate for \tilde{V}_{DC} may be derived:

\tilde{r}ₖe^{-jk\hat{φ}}^{ₒ}=\tilde{p}ₖe^{jφ}^{ₖ}e^{-jk\hat{φ}}^{ₒ}+\tilde{V}_{DC}e^{-jk\hat{φ}}^{ₒ}

\tilde{r}ₖe^{-jk\hat{φ}}^{ₒ}=\tilde{p}ₖe^{j(φ}^{ₖ}^{-k\hat{φ}}^{ₒ}⁾+\tilde{V}_{DC}e^{-jk\hat{φ}}^{ₒ}

$$\begin{matrix}{\sum }_{k} {\tilde{r}}_{k} {ⅇ}^{- j k {\hat{φ}}_{o}} = {\sum }_{k} {\tilde{p}}_{k} {ⅇ}^{j ( {φ}_{k} - k {\hat{φ}}_{o} )} + {\tilde{V}}_{D C} {\sum }_{k} {ⅇ}^{- j k {\hat{φ}}_{o}} \\ {\tilde{V}}_{D C} = \frac{{\sum }_{k} {\tilde{r}}_{k} {ⅇ}^{- j k {\hat{φ}}_{o}} - {\sum }_{k} {\tilde{p}}_{k} {ⅇ}^{j ( {φ}_{k} - k {\hat{φ}}_{o} )}}{{\sum }_{k} {ⅇ}^{- j k {\hat{φ}}_{o}}}\end{matrix}$$

Assuming that the frequency estimate is accurate, the quantity (φₖ−k\hat{φ}ₒ) would be very small, such that the DC offset is given by:

$${\tilde{V}}_{D C} = \frac{{\sum }_{k} {\tilde{r}}_{k} {ⅇ}^{- j k {\hat{φ}}_{o}} - {\sum }_{k} {\tilde{p}}_{k}}{{\sum }_{k} {ⅇ}^{- j k {\hat{φ}}_{o}}} \qquad Equation ( 2 )$$

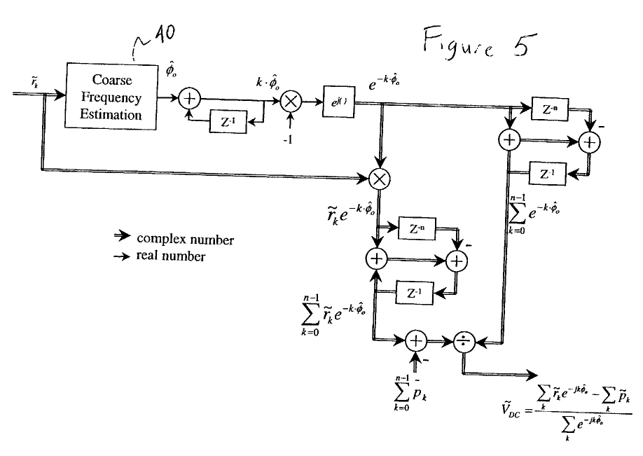

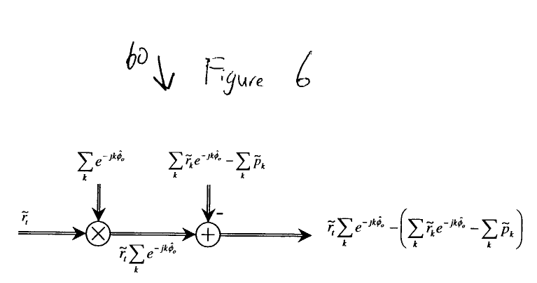

For an IEEE 802.11a waveform, the second term in the numerator of Equation (2) is very small or zero and can be neglected. FIG. 5 illustrates a z-transform implementation of Equation (2). In frequency estimation block 40, \hat{φ}ₒ is derived according to the present invention as discussed herein. Although the approach of FIG. 5 is feasible, the required division would entail considerable complexity when implemented in hardware. It will be appreciated that the DC offset estimation techniques disclosed herein may be implemented in either hardware or software. A software approach would avoid the complexities of the hardware division required to implement the DC offset estimation discussed with respect to FIG. 5. However, dedicated state machines implemented, e.g., in an ASIC, will typically provide greater processing speed.

Because a dedicated hardware approach is desirable but, if implemented based upon the z-transform representation of FIG. 5, would involve considerable complexity, an alternate approach is as follows. A DC offset mitigation using the estimate provided by the Equation (2) would be performed on samples \tilde{r}ₜ of data transmitted after the known samples of the preamble such that a corrected data sample Outₐ is given by:

$${Out}_{a} = {\tilde{r}}_{t} - {\tilde{V}}_{D C} = {\tilde{r}}_{t} - \frac{{\sum }_{k} {\tilde{r}}_{k} {ⅇ}^{- j k {\hat{φ}}_{o}} - {\sum }_{k} {\tilde{p}}_{k}}{{\sum }_{k} {ⅇ}^{- j k {\hat{φ}}_{o}}} \qquad Equation ( 3 )$$

Multiplication of Equation (3) with the numerator term

$$( {\sum }_{k} {ⅇ}^{- j k {\hat{φ}}_{o}} )$$

gives the following corrected data sample Out_{b}:

$$\begin{matrix}{Out}_{b} = {\tilde{r}}_{t} {\sum }_{k} {ⅇ}^{- j k {\hat{φ}}_{o}} - ( {\sum }_{k} {\tilde{r}}_{k} {ⅇ}^{- j k {\hat{φ}}_{o}} - {\sum }_{k} {\tilde{p}}_{k} ) \\ = {Out}_{a} ( {\sum }_{k} {ⅇ}^{- j k {\hat{φ}}_{o}} )\end{matrix} \qquad Equation ( 4 )$$

This factor

$$( {\sum }_{k} {ⅇ}^{- j k {\hat{φ}}_{o}} )$$

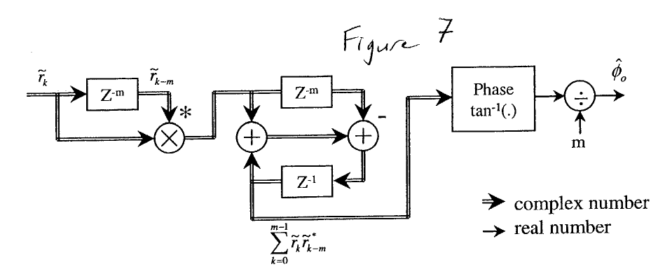

generates a known amplitude and phase change, which may be compensated for in subsequent demodulation to give the desired corrected data sample value Outₐ described previously. FIG. 6 illustrates a DC offset mitigation processor 60 performing the DC offset cancellation of Equation (4). Advantageously, no complex hardware is required—those of ordinary skill in the art will appreciate the numerous ways such a DC offset mitigation processor may be implemented using simple hardware such as shift registers, multipliers, and adders. Alternatively, such a DC offset mitigation processor may be performed using a microprocessor in a software-based approach. The techniques of the present invention to provide the frequency offset estimation factor \hat{φ}ₒ will now be discussed.

Frequency Offset Estimation Techniques

1. Estimating Frequency Offset with the DC Offset Component.

As can be seen from Equation (1), the kth received preamble sample \tilde{r}ₖ will be shifted in phase by an amount (k*\hat{φ}ₒ) with respect to the kth transmitted sample \tilde{p}ₖ of the preamble (ignoring, for the moment, the contribution from \tilde{V}_{DC}). Assuming the preamble comprises at least two identical sequences each having n samples, the following technique may be used. At the (k+n)th received sample of the preamble, the amount of phase shift will be (n+k)*\hat{φ}ₒ with respect to the (k+n)th transmitted sample in the preamble. But given the periodicity over n of the preamble, the (k+n)th transmitted sample is the same as the kth transmitted sample. Accordingly, if the (k+n)th received sample is multiplied by the complex conjugate of the kth received sample, the product is the phasor exp(j\hat{φ}ₒ*n) (ignoring the amplitude component, which has no effect on the phase). The frequency offset per sample \hat{φ}ₒ may thus be derived by taking the arc tangent of this phasor and dividing the result by n. However, this discussion ignores the contribution from the DC offset component. But for a small DC offset component, the estimation is quite good.

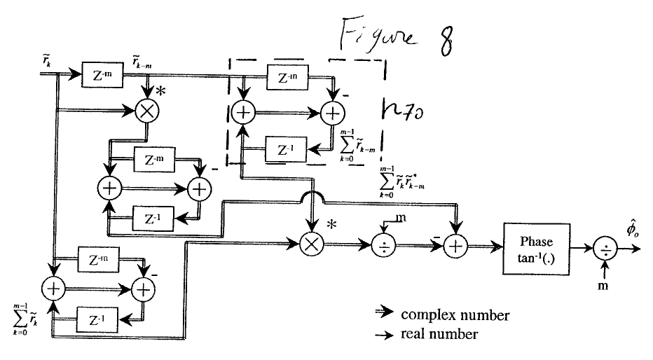

A z-transform implementation of the preceding algorithm is shown in FIG. 7, wherein the periodicity of the transmitted samples is represented by the variable “m.” To decrease noise, the kth received sample is multiplied by the complex conjugate of the (k−m)th received sample for all samples in the sequence (from k=0 to k=(m−1)) and then summed. Alternatively, greater or fewer samples could be summed depending upon the desired signal-to-noise ratio and latency requirements (where decreasing the number of samples would decrease latency but also decrease the signal-to-noise ratio). Although the DC offset component is estimated with this baseline frequency offset, the computation is considerably better than the simple averaging approach discussed previously—there are no error floors and the performance is only slightly degraded with the expected DC offset.

2. Estimating Frequency Offset Independently of the DC Offset Component.

In a second approach, an enhanced frequency offset is estimated independently from any effects of a DC offset component present in the system. The following is a derivation of this approach. As discussed previously, the kth received sample \tilde{r}ₖ of the preamble may be represented by:

\tilde{r}ₖ=\tilde{p}ₖe^{jφ}^{ₖ}+\tilde{V}_{DC} Equation (4)

Similarly, the (k−m)th sample of the preamble, where m is the number of samples in a sequence in the preamble is given by:

\tilde{r}ₖ₋ₘ=\tilde{p}ₖ₋ₘe^{jφ}^{ₖ₋ₘ}+\tilde{V}_{DC}=\tilde{p}ₖe^{jφ}^{ₖ}e^{-jmφ}^{ₒ}+\tilde{V}_{DC}

it follows that:

\tilde{r}ₖ₋ₘe^{jmφ}^{ₒ}=\tilde{p}ₖe^{jφ}^{ₖ}+\tilde{V}_{DC}e^{jmφ}^{ₒ} Equation (5)

From equations (4) and (5) it can be shown that:

$$\begin{matrix}\begin{matrix}{\sum }_{k} {\tilde{r}}_{k} {\tilde{r}}_{k - m}^{*} = {ⅇ}^{j m {φ}_{o}} {\sum }_{k} {\vert {\tilde{p}}_{k} \vert}^{2} + m {\vert {\tilde{V}}_{D C} \vert}^{2} + \\ {ⅇ}^{j m {φ}_{o}} {{\tilde{V}}_{D C} ( {\sum }_{k} {\tilde{p}}_{k} {ⅇ}^{j {φ}_{k}} )}^{*} + {\tilde{V}}_{D C}^{*} ( {\sum }_{k} {\tilde{p}}_{k} {ⅇ}^{j {φ}_{k}} )\end{matrix} \\ and \\ \begin{matrix}( {\sum }_{k} {\tilde{r}}_{k} ) {( {\sum }_{k} {\tilde{r}}_{k - m} )}^{*} = {ⅇ}^{j m {φ}_{o}} {\vert {\sum }_{k} {\tilde{p}}_{k} {ⅇ}^{j {φ}_{k}} \vert}^{2} + {\vert m {\tilde{V}}_{D C} \vert}^{2} + \\ m {ⅇ}^{j m {φ}_{o}} {{\tilde{V}}_{D C} ( {\sum }_{k} {\tilde{p}}_{k} {ⅇ}^{j {φ}_{k}} )}^{*} + m {\tilde{V}}_{D C}^{*} ( {\sum }_{k} {\tilde{p}}_{k} {ⅇ}^{j {φ}_{k}} )\end{matrix} \\ such that : \\ {\sum }_{k} {\tilde{r}}_{k} {\tilde{r}}_{k - m}^{*} - \frac{1}{m} ( {\sum }_{k} {\tilde{r}}_{k} ) {( {\sum }_{k} {\tilde{r}}_{k - m} )}^{*} = {ⅇ}^{j m {φ}_{o}} {\sum }_{k} {\vert {\tilde{p}}_{k} \vert}^{2} - \frac{1}{m} {ⅇ}^{j m {φ}_{o}} {\vert {\sum }_{k} {\tilde{p}}_{k} {ⅇ}^{j {φ}_{k}} \vert}^{2}\end{matrix}$$

The preceding equation may be factored as follows:

$${\sum }_{k} {\tilde{r}}_{k} {\tilde{r}}_{k - m}^{*} - \frac{1}{m} ( {\sum }_{k} {\tilde{r}}_{k} ) {( {\sum }_{k} {\tilde{r}}_{k - m} )}^{*} = {ⅇ}^{j m {φ}_{o}} ( {\sum }_{k} {\vert {\tilde{p}}_{k} \vert}^{2} - \frac{1}{m} {\vert {\sum }_{k} {\tilde{p}}_{k} {ⅇ}^{j {φ}_{k}} \vert}^{2} )$$

Because the factor

$$( {\sum }_{k} {\vert {\tilde{p}}_{k} \vert}^{2} - \frac{1}{m} {\vert {\sum }_{k} {\tilde{p}}_{k} {ⅇ}^{j {φ}_{k}} \vert}^{2} )$$

is a real number, the estimated phase shift \hat{φ}ₒ per received preamble sample from this enhanced technique is thus given by:

$${φ}_{o} = \frac{1}{m} phase \{ {\sum }_{k} {\tilde{r}}_{k} {\tilde{r}}_{k - m}^{*} - \frac{1}{m} ( {\sum }_{k} {\tilde{r}}_{k} ) {( {\sum }_{k} {\tilde{r}}_{k - m} )}^{*} \}$$

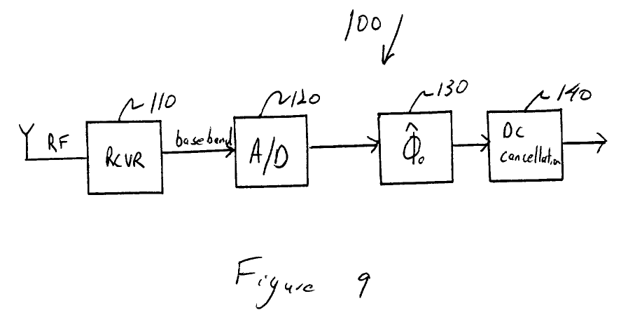

FIG. 8 is the z-transform implementation of this enhanced frequency offset estimate that is independent of effects from the DC offset component. Those of ordinary skill in the art will appreciate that a number of different state machines may be designed to implement this enhanced frequency offset estimation technique. For example, delay block 70, for both the I and Q components, may be implemented using shift register 20 and flip-flop 22 discussed with respect to FIG. 4. Similar delay blocks also required for this technique may be implemented in that fashion as well.

Regardless of how the frequency offset is estimated, the present invention provides an enhanced DC offset mitigation technique that is robust with respect to frequency offset effects. FIG. 9 illustrates a receiver 100 configured to perform this DC offset mitigation technique. A direct downconversion receiver 110 receives an RF signal and provides an analog baseband signal to an analog-to-digital converter 120. Analog-to-digital converter 120 digitizes the analog baseband signal and provides the resulting received signal samples to a frequency offset estimation state machine 130. State machine 130 may perform either frequency offset technique discussed herein to provide the estimated frequency-offset-induced phase shift \hat{φ}ₒ between each received sample of the preamble. DC cancellation state machine 140 receives the digitized baseband samples and the phase shift estimation factor \hat{φ}ₒ to cancel the DC offset component according to the techniques disclosed herein. This cancellation may involve the complex division discussed with respect to FIG. 5 or be performed as discussed with respect to FIG. 6. In an alternate embodiment, state machines 130 and 140 may be combined.

Although the present invention has been described with respect to an IEEE 802.11a based communication system, it may be applied to any communication scheme that transmits data that is prepended with a predetermined periodic signal. Because the properties of this predetermined periodic signal are known apriori by the receiver, the received samples from this predetermined packet may be exploited according to the present invention to mitigate the DC offset component despite the presence of a frequency offset between the transmitter and the receiver. For example, if the predetermined signal is periodic over n samples, a given sample of the predetermined signal should have the same phase as a sample delayed with respect to the given sample by n samples. By examining the phase shift between these two samples, the frequency offset estimation may be performed according to the techniques disclosed herein. Using this frequency offset estimate and the known values of the transmitted predetermined signal samples, the DC offset component for the received predetermined signal samples may also be derived according to the techniques disclosed herein. This DC offset component may then be cancelled in any data samples received subsequent to the predetermined signal. Accordingly, although the invention has been described with respect to particular embodiments, this description is only an example of the invention's application and should not be taken as a limitation. Consequently, the scope of the invention is set forth in the following claims.

What is claimed is:

1. A method of mitigating a DC offset component, comprising:
(a) estimating a frequency-offset-induced phase shift \hat{φ}ₒ between successive received samples of a predetermined signal by comparing at least one sample in a first period of the predetermined signal with the corresponding at least one received sample in a second period of the predetermined signal;
(b) estimating a DC offset component in the received samples of the predetermined signal after compensating the received samples according to the estimated phase shift \hat{φ}ₒ; and
(c) mitigating a DC offset component in a received data sample according to the estimated DC offset.

2. The method of claim 1, wherein the first and second period of the predetermined signal each comprises n samples, and wherein act (c) comprises:
(e) forming the sum of the n successive received samples of the a period of the predetermined signal, each received sample in the sum being rotated in phase according to the estimated phase shift \hat{φ}ₒ such that a jth received sample is rotated in phase by an amount −j times the phase shift \hat{φ}ₒ;
(f) subtracting the sum of n transmitted samples for a period of the predetermined signals from the result from act (e); and
(g) adjusting the received data sample using the result from act (f).

3. The method of claim 2, wherein act (g) comprises:
(i) forming the sum:
$${\sum }_{k = 0}^{n - 1} {ⅇ}^{- j ( k {\hat{φ}}_{o} )}$$
(j) dividing the result from act (f) with the result from act (i); and
(k) subtracting the result from act (j) from the received data sample.

4. The method of claim 2, wherein act (g) comprises:
(i) multiplying the received data sample by the sum:
$${\sum }_{k = 0}^{n - 1} {ⅇ}^{- j ( k {\hat{φ}}_{o} )}$$
(j) subtracting the result from act (f) from the result from act (i).

5. The method of claim 1, wherein the estimation in act (a) is made without compensating for a DC offset component in the received samples of the predetermined signal.

6. The method of claim 5, wherein act (a) comprises extracting the phase difference between the at least one received sample in the first period and the corresponding at least one received sample in the second period.

7. The method of claim 5, wherein act (a) comprises averaging the phase difference between each received sample in the first period and the corresponding received sample in the second period.

8. The method of claim 7, wherein the predetermined signal is a preamble of an IEEE 802.11a modulated data signal.

9. The method of claim 5, wherein the estimation in act (a) is made independently from a DC offset component in the received samples of the predetermined signal.

10. The method of claim 9, wherein act (a) comprises: for each given sample \tilde{r}ₖ in the first period and the corresponding sample \tilde{r}*ₖ₋ₙ in the second period, calculating \tilde{φ}ₒ such that:
$${\hat{φ}}_{o} = phase ( {\sum }_{k = 0}^{n - 1} \{ {\tilde{r}}_{k} {\tilde{r}}_{k - n}^{*} \} - \frac{1}{n} ( {\sum }_{k = 0}^{n - 1} {\tilde{r}}_{k} ) {( {\sum }_{k = 0}^{n - 1} {\tilde{r}}_{k - n} )}^{*} ) .$$

11. The method of claim 10, wherein the predetermined signal is a preamble of an IEEE 802.11a modulated data signal.

12. A baseband processor for a received direct downconverted predetermined signal, wherein the received predetermined signal is subject to a frequency offset, comprising:
an analog-to-digital converter for digitizing samples of the received predetermined signal; and
a state machine configured to estimate a frequency-offset-induced phase shift \hat{φ}ₒ between successive received samples of the predetermined signal by comparing at least one sample in a first period of the predetermined signal with the corresponding at least one received sample in a second period of the predetermined signal, wherein the state machine is further configured to estimate a DC offset component in the received samples of the predetermined signal after compensating the received samples according to the estimated phase shift \hat{φ}ₒ.

13. The baseband processor of claim 12, wherein the state machine comprises an application-specific-integrated circuit (ASIC).

14. The baseband processor of claim 12, wherein the state machine is configured to estimate \hat{φ}ₒ without compensating for a DC offset component in the received samples of the predetermined signal.

15. The baseband processor of claim 12, wherein the state machine is configured to estimate \hat{φ}ₒ independently from a DC offset component in the received samples of the predetermined signal.

16. The baseband processor of claim 14, wherein the predetermined signal is a preamble of an IEEE 802.11a modulated data signal.

17. The baseband processor of claim 15, wherein the predetermined signal is a preamble of an IEEE 802.11a modulated data signal.
